(19) United States
(12) Patent Application Publication
(10) Pub. No.: US 2001/0014528 A1
(43) Pub. Date: Aug. 16, 2001

(54) METHOD OF MANUFACTURING UNLANDED VIA PLUG

(76) Inventor: CHIEN-HUA TSAI, TAICHUNG (TW)

Correspondence Address: JC PATENTS INC, 1340 REYNOLDS AVENUE, SUITE 114, IRVINE, CA, 92614

(21) Appl. No.: 09/213,699

(22) Filed: Dec. 17, 1998

(30) Foreign Application Priority Data
Sep. 3, 1998 (TW) 87114613

(51) Int. Cl. H01L 21/4763

(52) U.S. Cl. 438/637

(57) ABSTRACT

A method of manufacturing an unlanded via plug comprises the steps of providing a substrate having a conductive wire on the top surface of the substrate. A dielectric layer is formed on the substrate with a surface level between the top surface and the bottom surface of the conductive wire. An etching stop layer is formed over the substrate and the etching stop layer is planarized until exposing the surface of the conductive wire. Another dielectric layer is formed over the substrate, and then the dielectric layer is patterned to form a via hole and expose the conductive wire. Thereafter, the via hole is filled with a conductive material to form a via plug.

### CROSS-REFERENCE TO RELATED APPLICATION

This application claims the priority benefit of Taiwan application serial no. 87114613, filed Sep. 3, 1998, the full disclosure of which is incorporated herein by reference.

### BACKGROUND OF THE INVENTION

1. Field of the Invention

The present invention relates to a method of manufacturing multilevel metal interconnects. More particularly, the present invention relates to a method of manufacturing an unlanded via plug.

2. Description of the Related Art

Due to the increasingly high integration of ICs, chips simply cannot provide sufficient areas for interconnection manufacturing. Therefore, in accord with the increased interconnect manufacturing requirements of miniaturized MOS transistors, it is increasingly necessary for IC manufacturing to adopt a design with more than two metal layers. In particular, a number of function-complicated products, such as microprocessors, even require 4 or 5 metal layers to complete the internal connections. Generally, an inter-metal dielectric (IMD) layer is used to electrically isolate two adjacent metal layers from each other. Moreover, a conductive layer used to electrically connect the two adjacent metal layers is called a via plug in the semiconductor industry.

In a prior method for manufacturing a via plug in a multilevel metal interconnect process, a dielectric layer is first formed on the conductive wire. Then, the dielectric layer is patterned to form a via hole in the dielectric layer by etching. Next, a conductive layer is deposited in the via hole, forming a so-called via plug. The above-stated steps are then repeated to completely implement a multilevel metal interconnect process.

With the decrease of wire width in ICs and the increase of integration of ICs, misalignment easily occurs as the dielectric layer is patterned to form the via hole. Misalignment causes the dielectric layer to be etched through by etching gas, thus, the via plug formed sequentially is electrically coupled to the conductive region in the substrate. Therefore device failure is results.

FIG. 1A through 1C are schematic, cross-sectional views of the conventional process for manufacturing an unlanded via plug. As shown in FIG. 1A, a substrate 100 having a conductive wire 102 on the surface of the substrate is provided. The conductive wire 102 has an anti-reflection layer 104 on its surface. The anti-reflection layer 104 usually is made from titanium nitride. Thereafter, a dielectric layer 106 with a low dielectric constant is formed on the substrate 100. Next, a dielectric layer 108 is formed on the dielectric layer 106, and then the dielectric layer 108 is planarized.

Next, as shown in FIG. 1B, using the anti-reflection layer 104 as an etching stop layer, the dielectric layers 106 and 108 are patterned to form the dielectric layer 106a and 108a having a via hole 110.

Referring to FIG. 1C, a conductive material is deposited to fill the via hole 110 and form a via plug 114. In this manner, the manufacturing of the unlanded via plug is completed.

Referring to FIG. 1D, while the dielectric layer 106 and 108 are patterned to form the via hole 110, misalignment occurs. Because of the misalignment, the via hole 110a passes through the dielectric layer 106a to expose a portion of the substrate 100. The via plug 114a is formed in the via hole 10a and the via plug 114a is electrically coupled to the substrate 100. When the via plug 114a is electrically coupled to the conductive region previously formed in the substrate 100, it results in device failure. Conventionally, there are two methods to solve the problem caused by the misalignment in performing the etching process with wire width below 0.18 μm. One is to inspect the particles of the anti-reflection layer 104a, and the other is to calculate the etching time to determine the etching stop moment.

In the first method mentioned above, the area exposed by the via hole 110a is so small and the thickness of the anti-reflection layer 104 is so thin that very few particles of the anti-reflection layer are produced during the etching process. Furthermore, the portion of the anti-reflection layer 104 exposed by the via hole 110a is etched completely in a short time before the particles being detected. As the etching gas etches through the dielectric layer 106a, the particles of the anti-reflection layer 104 may not even be detected. Thus, the via plug 114a is electrically coupled to the conductive region in the substrate 100, and results in device failure.

In the second method, the thickness of the dielectric layer is different for each process. Moreover, the factors of calculating the etching time include the thickness of the dielectric layer, the material of the dielectric layer, the material of the anti-reflection layer and the etching rate of the conductive wire, and all the factors are different every time. Therefore, the method of calculating the etching time is not a good way to determine the etching stop moment.

### SUMMARY OF THE INVENTION

Accordingly, the present invention provides a method of manufacturing an unlanded via plug. The invention can solve the problem of the etching gas etching through the dielectric layer due to the misalignment when the etching step is performed in wire width below 0.18 μm process. And thus, the problem of device failure induced by the via plug making contact with the conductive region can be overcome.

To achieve these and other advantages and in accordance with the purpose of the invention, as embodied and broadly described herein, the invention provides a substrate having a conductive wire on the top surface of the substrate. A dielectric layer is formed on the substrate with a surface level between the top surface and the bottom surface of the conductive wire. An etching stop layer is formed over the substrate and the etching stop layer is planarized until exposing the surface of the conductive wire. Another dielectric layer is formed over the substrate, and then the dielectric layer is patterned to form a via hole and expose the conductive wire. Thereafter, the via hole is filled with a conductive material to form a via plug. The etching stop layer is the characteristic of the present invention, and it is an effective etching stop point during performance of the etching process. Because the etching stop layer and the dielectric layer have different etching rate, the etching stop layer can react with the gas source of plasma etching process to form polymers. When lithography and etching is utilized to form a via hole, the etching stop layer can prevent the etchant from etching through the substrate even while a misalignment occurs. Furthermore, the device failure caused by the via plug electrically coupling to the substrate can be avoided.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIGS. 1A through 1C are schematic, cross-sectional views of the conventional process for manufacturing the unlanded via plug;

FIG. 1D is a schematic, cross-sectional view of the unlanded via plug induced by misalignment;

FIGS. 2A through 2G are schematic, cross-sectional views of the process for manufacturing the unlanded via plug in a preferred embodiment according to the invention; and

FIG. 2H is a schematic, cross-sectional view of the unlanded via plug induced by misalignment in a preferred embodiment according to the invention.

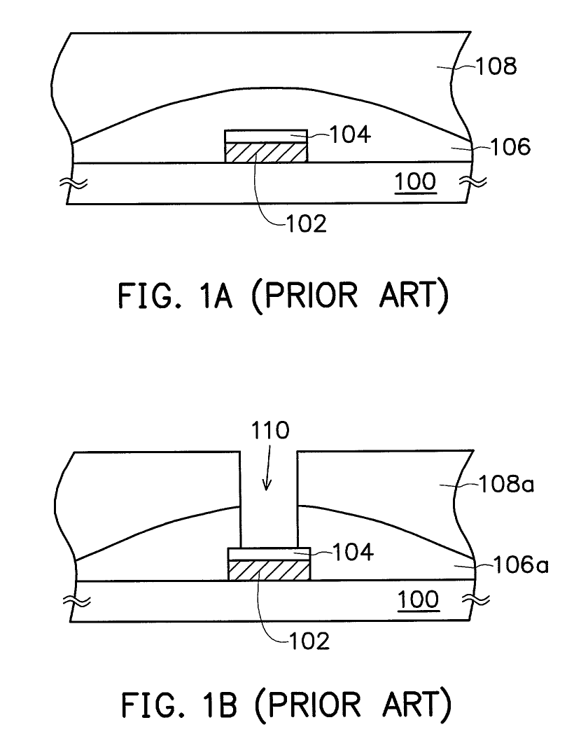

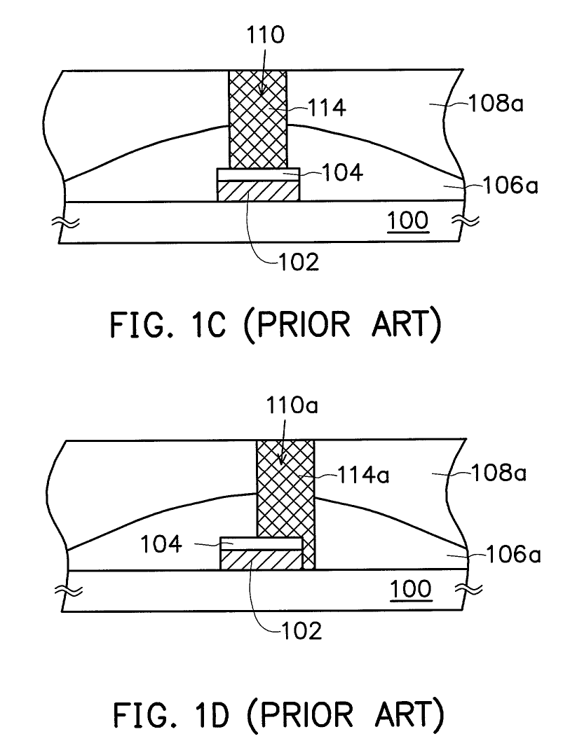

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

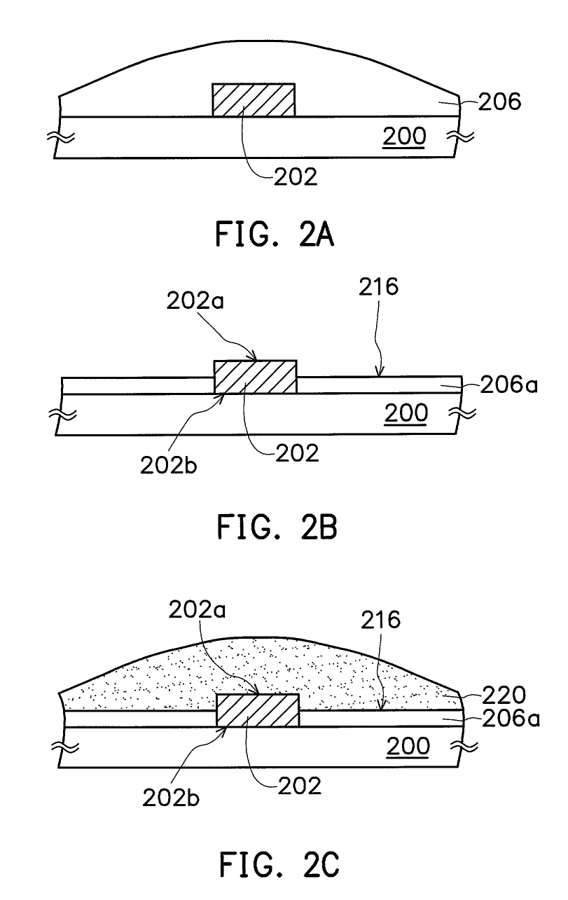

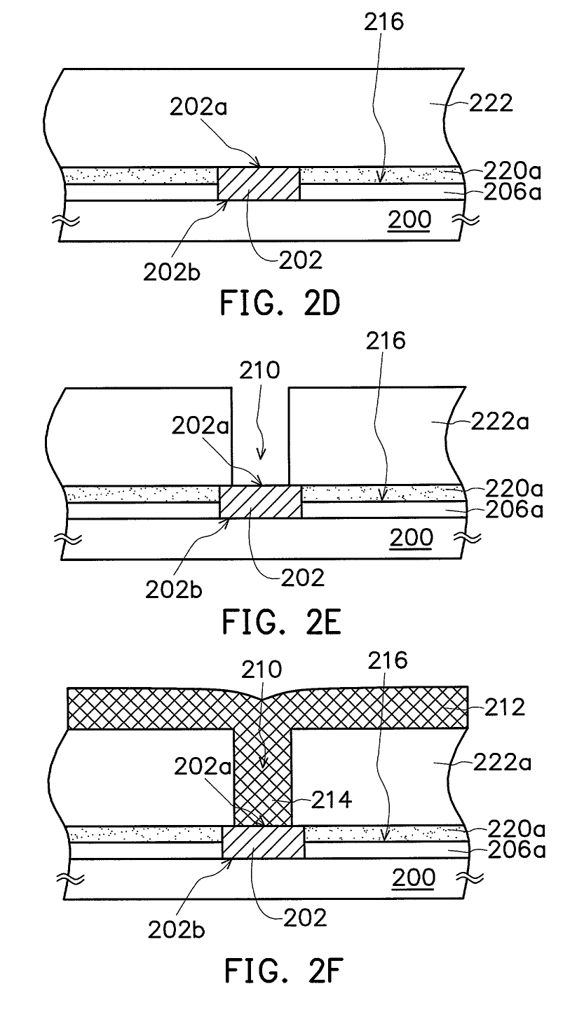

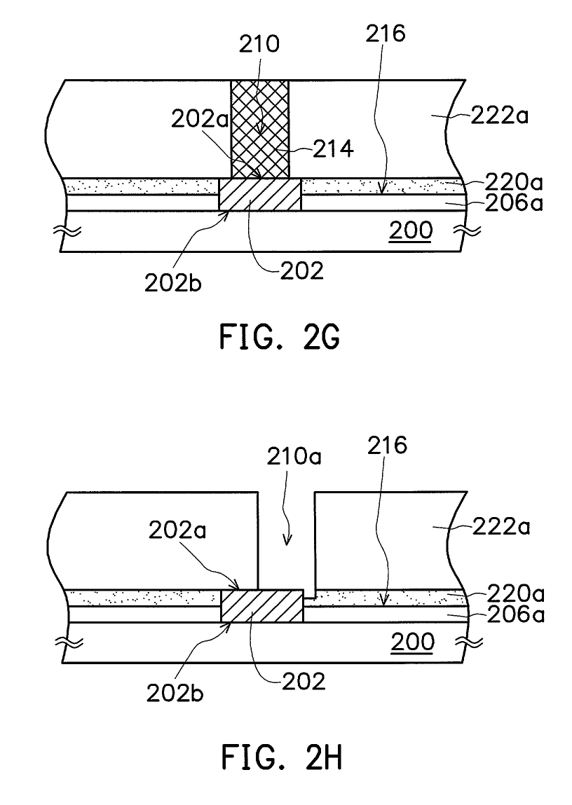

FIGS. 2A through 2G are schematic, cross-sectional views of the process for manufacturing the unlanded via plug in a preferred embodiment according to the invention.

First, as shown in FIG. 2A, a substrate 200 having a conductive wire 202 on a surface of the substrate 200 is provided. (For the sake of simplicity, the devices in the substrate 200 are not shown.) The conductive wire 202 can be made, for example, from copper, aluminum or other conductive materials. Thereafter, a dielectric layer 206 with a low dielectric constant such as a silicon oxide layer is formed on the substrate 200. The method of forming the dielectric layer 206 includes high-density plasma chemical vapor deposition.

As shown in FIG. 2B, a portion of the dielectric layer 206 is removed until the surface level of the dielectric layer 206a is between the top surface 202a and the bottom surface 202b of the conductive wire 202. The method of removing the portion of the dielectric layer 206 includes etching back or chemical-mechanical polishing in coordination with etching back.

Referring to FIG. 2C, an etching stop layer 220 such as a silicon oxide is formed over the substrate 200. The method of forming the etching stop layer 220 includes chemical vapor deposition. A preferred etching stop layer is a TEOS silicon oxide layer formed by low-pressure chemical vapor deposition using TEOS as gas source.

As shown in FIG. 2D, the etching stop layer 220 is planarized to expose the top surface 202a of the conductive wire 202. The remaining etching stop layer 220 forms a etching stop layer 220a. The method of planarizing the etching stop layer 220 includes chemical-mechanical polishing. A dielectric layer 222 such as a silicon oxide layer is formed on the etching stop layer 220a and the conductive wire 202, and then the dielectric layer 222 is planarized. It is important that the dielectric layer 222 and the etching stop layer 220a have different etching rates. The method of forming dielectric layer 222 includes plasma enhanced chemical vapor deposition. The method of planarizing the dielectric layer 222 includes chemical-mechanical polishing.

Referring to FIG. 2E, the dielectric layer 222 is patterned to expose a portion of the conductive wire 202 and to convert the dielectric layer 222 into a dielectric layer 222a having a via hole 210. The method of forming the via hole 210 includes dry etching. When using a TEOS silicon oxide layer as the etching stop layer 220, the preferred plasma etching gas source is C₄F₈/CO/Ar/O₂, and the preferred ratio of gas source C₄F₈/CO/Ar is about 3≈4/50≈100/400≈500.

Referring to FIG. 2F, a conductive layer 212 is formed on the dielectric layer 222 and fills the via hole 210 to form a via plug 214. The conductive layer 212 can be made, for example, from copper, aluminum or other conductive materials.

As shown in FIG. 2G, a portion of the conductive layer 212 is removed to expose the surface of the dielectric layer 222a, and then the unlanded via plug is formed.

As shown in FIG. 2H, it is often that misalignment occurs while the dielectric layer 222 shown in FIG. 2D is patterned to form the via hole 210. Since the etching stop layer 220a and the dielectric layer 222a have different etching rates and the etching gas reacts with the etching stop layer 220a to form polymers which can resist the etching gas, the etching stop layer effectively stops the etching process. The etching process can be stopped at the etching stop layer while the etching gas etches through the dielectric layer 222a to expose only a portion of the etching stop layer 220a. The misalignment in the conventional processing techniques leads to etching through the dielectric layer by the etching gas and causes the via plug to be electrically coupled to the substrate 200, which results in device failure. The present invention overcomes the problem of the conventional processing techniques by providing an effective etching stop point.

In the preferred embodiment according to the present invention, a portion of the dielectric layer 206 is removed until the surface of the dielectric layer 206a is between the top surface and the bottom surface of the conductive wire 202 before the dielectric layer 222 is formed. The etching stop layer 220 is formed over the substrate 200 and planarized to have a substantially same surface level as the top surface of the conductive wire 202. The etching stop layer 220a and the dielectric layer 222a have different etching rates. The etching gas reacts with the etching stop layer 220a to form polymers which can resist the etching gas. During the etching step performed sequentially to formed the via hole 210, the etching stop layer 220a effectively stops the etching process, so that the etchant can not etch through the dielectric layer 206a, thus avoiding the misalignment problem.

The present invention has the following advantages:

1. An etching stop layer is formed between two dielectric layers, and the etching stop layer can react with the plasma etching gas source to form a polymer layer. The polymers can prevent the etching stop layer from being corroded by the etching gas, so they can solve the problem induced by misalignment.

2. It is easy to determine the etching stop point by using the present invention. Conventionally, the anti-reflection layer is used as an etching stop layer. But because the thickness of the anti-reflection layer is very thin and signal detected from the anti-reflection layer is very weak during the etching process, the etching gas can easily etch through the dielectric layer. The present invention can overcome the weakness induced in the conventional process by misalignment.

3. It is easy to determine the etching stop point by using the present invention. Conventionally, the etching time is calculated to control the etching stop point. But the material and the thickness of the dielectric layer are different every time, which complicates the control process. Thus, the present invention can solve the disadvantages of the conventional method which is utilized to determine the etching stop moment.

4. The present invention and the conventional process techniques are compatible; thus the present invention is suitable for the manufacturers to utilize.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method of manufacturing an unlanded via plug, comprising the steps of:
providing a substrate having a conductive wire on the substrate, the conductive wire having a top surface and a bottom surface;
forming a first dielectric layer on the substrate with a surface level between the top surface and the bottom surface of the conductive wire;
forming an etching stop layer with a substantially same surface level as the top surface of the conductive wire;
forming a second dielectric layer with a via hole exposing the conductive wire over the substrate; and
filling the via hole with a conductive material to form a via plug.

2. The method of claim 1, wherein the etching stop layer and the second dielectric layer have different etching rates.

3. The method of claim 2, wherein the etching stop layer includes silicon oxide.

4. The method of claim 3, wherein the step of forming the etching stop layer includes low-pressure chemical vapor deposition using TEOS as the gas source.

5. The method of claim 2, wherein the step of forming the second dielectric layer includes plasma enhanced chemical vapor deposition, and the second dielectric layer includes silicon oxide.

6. The method of claim 2, wherein the step of forming the via hole includes plasma etching using C₄F₈/CO/Ar/O₂ as the gas source.

7. The method of claim 6, wherein the ratio of the gas source C₄F₈/CO/Ar is in a range of about 3≈4/50≈100/400≈500.

8. The method of claim 1, wherein the step of forming the etching stop layer further comprises chemical-mechanical polishing.

9. The method of claim 1, wherein the first dielectric layer includes silicon oxide.

10. The method of claim 9, wherein the step of forming the first dielectric layer includes high-density plasma chemical vapor deposition.

11. The method of claim 1, wherein the step of forming the first dielectric layer further comprises etching back.

12. The method of claim 1, wherein the step of forming the first dielectric layer further comprises chemical-mechanical polishing in coordination with etching back.

13. A method of manufacturing an unlanded via plug, comprising the steps of:
providing a substrate having a conductive wire on the substrate, the conductive wire having a top surface and a bottom surface;
forming a first dielectric layer on the substrate with a surface level between the top surface and the bottom surface of the conductive wire;
forming a TEOS etching stop layer over the substrate;
planarizing the TEOS etching stop layer to expose the top surface of the conductive wire;
forming a second dielectric layer over the substrate;
performing plasma etching using C₄F₈/CO/Ar/O₂ as gas source to etch the second dielectric layer and to form a via hole until a portion of the conductive wire is exposed; and
filling the via hole with a conductive material to form a via plug.

14. The method of claim 13, wherein the TEOS etching stop layer and the second dielectric layer have different etching rate.

15. The method of claim 14, wherein the step of forming the TEOS etching stop layer includes low-pressure chemical vapor deposition.

16. The method of claim 14, wherein the step of forming the second dielectric layer includes plasma enhanced chemical vapor deposition, and the second dielectric layer includes silicon oxide.

17. The method of claim 14, wherein the ratio of the gas source C₄F₈/CO/Ar is in a range of about 3≈4/50≈100/400≈500.

18. The method of claim 13, wherein the step of planarizing the TEOS etching stop layer includes chemical-mechanical polishing.

19. The method of claim 13, wherein the first dielectric layer includes silicon oxide.

20. The method of claim 19, wherein the step of forming the first dielectric layer includes high-density plasma chemical vapor deposition.
